(19) United States
(12) Patent Application Publication
(10) Pub. No.: US 2023/0197368 A1
(43) Pub. Date: Jun. 22, 2023

(54) REMOTE CONTROLLER WITH WATERPROOF FUNCTION

(71) Applicant: KYUNG IN ELECTRONICS CO.,LTD, Seoul (KR)

(72) Inventors: Bum Seok KIM, Anyang-si (KR); Jung Il AN, Seoul (KR)

(21) Appl. No.: 18/065,561

(22) Filed: Dec. 13, 2022

(30) Foreign Application Priority Data
Dec. 22, 2021 (KR) 10-2021-0184491

(51) Int. Cl. H01H 9/02; H05K 5/02; H05K 5/00

(52) U.S. Cl. CPC H01H 9/0242; H05K 5/0214; H05K 5/0008

(57) ABSTRACT

A remote control with a waterproof function, according to an embodiment of the present invention, includes a case including an upper case having a plurality of button holes and a lower case assembled to the upper case at a lower portion of the upper case, a printed circuit board PCB embedded between the upper case and the lower case, and a rubber keypad, which is embedded between the upper case and the lower case so as to mounted to surround the side portions of the PCB and has a plurality of buttons that pass through the plurality of button holes and barrier parts that come into close contact with the inner surface of the upper case and the inner surface of the lower case, where the upper case and the lower case come into contact with each other.

### CROSS-REFERENCE TO RELATED APPLICATION

This application claims priority under 35 U.S.C § 119 to Korean Patent Application No. 10-2021-0184491 filed in the Korean Intellectual Property Office on Dec. 22, 2021, the entire contents of which are hereby incorporated by reference.

### TECHNICAL FIELD

The present invention relates to a remote control with a waterproof function and, more particularly, to a remote control with a waterproof function, in which a waterproof structure is applied to each gap of a case so as to prevent water or moisture from penetrating into the case, thereby enhancing durability.

### TECHNICAL FIELD

The present invention relates to a remote control with a waterproof function and, more particularly, to a remote control with a waterproof function, in which a waterproof structure is applied to each gap of a case so as to prevent water or moisture from penetrating into the case, thereby enhancing durability.

### BACKGROUND ART

In general, a remote control capable of remotely controlling operations of a home appliance is used to promote consumer convenience.

However, as the frequency of using electronic products in humid or wet places such as bathrooms, hot springs, swimming pools, etc. increases recently, the demand for remote controls having a waterproof function is increasing.

A conventional remote control typically includes a case having an upper case and a lower case that are interlocked and combined, a keypad built into the case in a state where buttons are exposed through the through holes of the upper case, a PCB, which detects a button press signal and transmits an operation signal accordingly, and a battery built into the case so as to supply power.

However, in such a conventional remote control, water or moisture may penetrate through the gap between the upper case and the lower case, the gap between the buttons and the through holes of the upper case, and the gap between a cover that covers the battery and the lower case.

In this case, since the PCB or various electronic components built in the case are very vulnerable to water, the remote control may malfunction, thereby causing inconvenience to a user and trouble for repair or replacement.

In order to solve the problems, a remote control having a waterproof function has been developed in the past, but even in this case, it is not possible to ensure waterproofing for all gaps in the remote control and to secure sufficient durability. Therefore, there is a risk of failure and damage due to penetration of liquid such as water.

Accordingly, there is a need to develop a remote control having a new configuration that can implement an excellent waterproof function over the entire area of the remote control and has excellent durability.

As related prior art, there is Korean Patent Registration No. 10-620721 [Title of Invention: remote control] and the like.

### SUMMARY

### Technical Problem

According to an embodiment of the present invention, a waterproof structure is applied to each gap of a case so as to prevent water or moisture from penetrating into the case, thereby enhancing durability.

The problems to be solved by the present invention are not limited to the problems mentioned above, and other problems not mentioned will be clearly understood by those skilled in the art from the following description.

### Problem Solving Means

According to an embodiment of the present invention, a remote control with a waterproof function, may include a case including an upper case having a plurality of button holes and a lower case assembled to the upper case at a lower portion of the upper case, a printed circuit board PCB embedded between the upper case and the lower case, and a rubber keypad, which is embedded between the upper case and the lower case so as to be mounted to surround the side portions of the PCB and has a plurality of buttons that pass through the plurality of button holes and barrier parts that come into close contact with the inner surface of the upper case and the inner surface of the lower case, where the upper case and the lower case come into contact with each other.

According to one aspect of the present invention, the barrier parts may be provided on both sides of a mounting plate of the rubber keypad on which the plurality of button holes are provided, and when the upper case and the lower case are coupled to each other with the rubber keypad interposed between the upper case and the lower case, the inner surfaces of the side portions of the upper case and the inner surfaces of the side portions of the lower case come into close contact with the outer surfaces of the barrier parts so as to provide a waterproof function.

According to another aspect of the present invention, the rubber keypad provided with the barrier parts may be made of a rubber or silicone material, and when the rubber keypad is coupled to the upper case and the lower case with the barrier parts interposed between the upper case and the lower case, the outer surfaces of the barrier parts press the upper case and the lower case owing to the elastic force provided in the barrier parts so that the barrier parts come into close contact with the upper case and the lower case.

According to another aspect of the present invention, the rubber keypad may be provided with board insertion parts which protrude downward from both ends of the lower end portion of the mounting plate so as to surround the side portions of the PCB, and the width of the board insertion parts and the width of the PCB correspond to each other so that the PCB is embedded in the case while being inserted into the board insertion parts.

According to another aspect of the present invention, protruding parts may be provided on any one of the side portions of the upper case or the side portions of the lower case, and recessed parts corresponding in shape to the protruding parts may be provided on the other one of the side portions of the upper case or the side portions of the lower case so as to come into surface contact with the protruding parts.

According to another aspect of the present invention, each of the plurality of button holes of the upper case includes a protruding rib that protrudes inward from the upper case, and when the rubber keypad is coupled to the upper case, the lower end of the protruding rib comes into close contact with the upper surface of the mounting plate of the rubber keypad, which is provided with the buttons.

According to another aspect of the present invention, a battery part may be further provided so that a battery is detachably coupled to a battery groove provided in the lower case.

According to another aspect of the present invention, the battery part includes a battery mounting frame in which the battery is mounted, a battery cover member provided at an end portion of the battery mounting frame so as to cover the battery groove, and a close contact member, which has an O-ring shape and is fitted into the battery mounting frame so as to be disposed on an inner surface of the battery cover member, wherein when the battery part is coupled to the battery groove, the close contact member comes into close contact with sidewalls, which form the battery groove, and the battery cover member.

According to another aspect of the present invention, the sidewalls that form the battery groove and the battery cover member are coupled by means of a screw in order to fix the battery cover member to the sidewalls that form the battery groove, and the screw is coupled in a region outside the contact member.

### Effect of the Invention

According to an embodiment of the present invention, a waterproof structure is applied to each gap of the case so as to prevent water or moisture from penetrating into the case, thereby enhancing durability.

In particular, by providing the waterproof function between the upper case and the lower case, between the buttons and the button holes, between the rubber keypad and the PCB, and between the battery part and the battery groove, it is possible to prevent failure due to penetration of water or moisture, etc.

### BRIEF DESCRIPTION OF THE DRAWINGS

FIG. 1 is a perspective view of a remote control with a waterproof function according to an embodiment of the present invention, which is in an assembled state.

FIG. 2 is an exploded perspective view of the remote control shown in FIG. 1.

FIG. 3 is a cross-sectional view of the remote control shown in FIG. 1.

FIG. 4 is a bottom view of the remote control shown in FIG. 2.

FIG. 5 is view for explaining the coupling structure of a battery part shown in FIG. 4, and

FIG. 6 is a view schematically showing a state in which the battery part shown in FIG. 5 is coupled to a battery groove.

### DETAILED DESCRIPTION

Advantages and/or features of the present invention and methods of achieving them will become apparent with reference to the detailed description of the following embodiment taken in conjunction with the accompanying drawings. However, the present invention is not limited to the embodiment disclosed below and will be implemented in various different forms, the embodiment is provided only to make the disclosure of the present invention complete and to completely inform those skilled in the art of the scope of the invention to which the present invention belongs, and the invention is only defined by the scope of the claims. Like reference numbers designate like elements throughout the specification.

Hereinafter, an embodiment of the present invention will be described in detail with reference to the accompanying drawings.

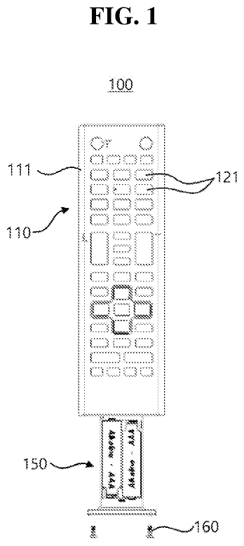

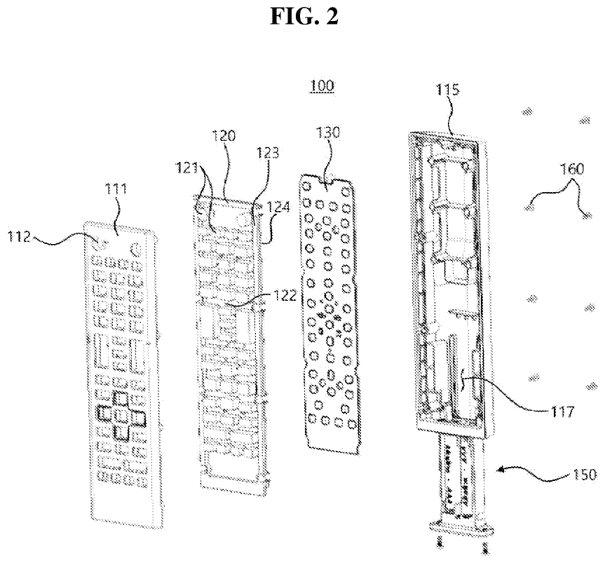

FIG. 1 is a perspective view of a remote control with a waterproof function according to an embodiment of the present invention, which is in an assembled state, FIG. 2 is an exploded perspective view of the remote control shown in FIG. 1.

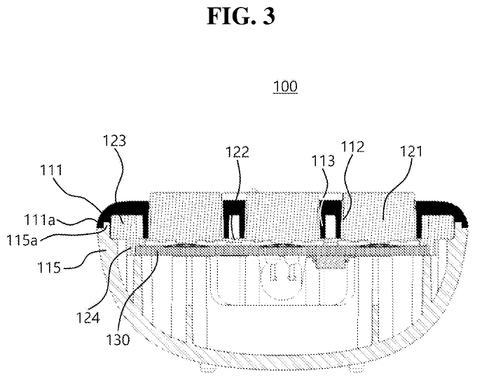

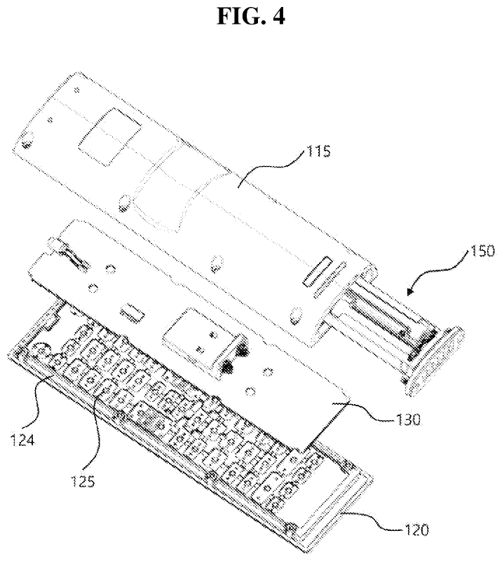

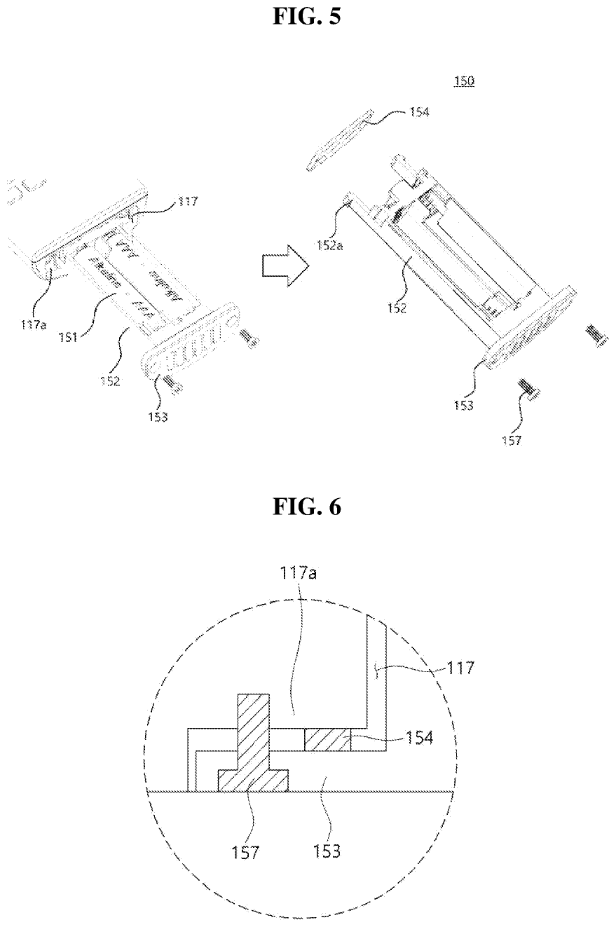

FIG. 3 is a cross-sectional view of the remote control shown in FIG. 1, FIG. 4 is a bottom view of the remote control shown in FIG. 2, FIG. 5 is view for explaining the coupling structure of a battery part shown in FIG. 4, and FIG. 6 is a view schematically showing a state in which the battery part shown in FIG. 5 is coupled to a battery groove.

As shown in the drawings, a remote control 100 with a waterproof function (hereinafter, referred to as “remote control”) according to an embodiment of the present invention, may include a case 110 having an upper case 111 and a lower case 115, a PCB 130 embedded in the case 110, a rubber keypad 120, which is mounted in the case 110 in a state, in which the PCB 130 is inserted, and is provided with barrier parts 123 for blocking between the case 110 and a plurality of buttons 121 that are exposed through the button holes 112 of the case 110, and a battery part 150 detachably coupled to a battery groove 117 of the case 110 while provided with a battery 151.

As shown in the drawings, a remote control 100 with a waterproof function (hereinafter, referred to as “remote control”) according to an embodiment of the present invention, includes a case 110 having an upper case 111 and a lower case 115, a PCB 130 embedded in the case 110, a rubber keypad 120, which is positioned on the PCB 130 in the case 110 and has a plurality of buttons 121 exposed through button holes 112 of the case 110, a battery part 150 detachably coupled to a battery groove 117 of the case 110 while provided with a battery 151.

With this configuration, the remote control 100 of this embodiment has an excellent waterproof function through the coupling of each component while firmly implementing the coupling of each component, so that, for example, water or moisture cannot penetrate into the remote control 100 and excellent durability can be provided.

When explaining each component, the case 110 of the present embodiment may include, as shown in FIG. 1 and FIG. 2, the upper case 111 having the plurality of button holes 112 and the lower case 115 assembled to the upper case 111 below the upper case 111. The upper case 111 and the lower case 115 may be coupled to each other by means of screws 160.

Referring to FIG. 3, protruding parts 115a are be provided protruding from the upper surfaces of the side portions of the lower case 115 and recessed parts 111a corresponding to the protruding parts 115a are be provided on the lower surfaces of the side portions of the upper case 111, so that the lower case 115 and the upper case 111 can be fitted and coupled to each other. Due to the male-female engagement structure of the case 110, the waterproof function may be enhanced.

Herein, the shapes and structures of the upper case 111 and the lower case 115 are not limited thereto, and contrary to the above example, the upper case 111 may be provided with the protruding parts and the lower case 115 may be provided with the recessed parts or, of course, it is also possible to provide other male and female engagement structures.

The upper case 111 of this embodiment is provided with the plurality of button holes 112 through which the buttons 121 of the rubber keypad 120, which will be described later, are disposed through. As will be described later, since a waterproof structure is applied to the gap between the button holes 112 and the buttons 121, it is possible to prevent water or moisture from entering the inside of the case 110.

The lower case 115 of this embodiment is provided with the battery groove 117, in which the battery part 150 can be mounted. The configuration and waterproof structure of the battery part 150 will be described later.

Meanwhile, the rubber keypad 120 of this embodiment may include, as shown in FIG. 1 to FIG. 3, particularly in FIG. 3,

a mounting plate 122, the plurality of buttons 121 provided on the upper surface of the mounting plate 122 so as to be inserted into and exposed through the button holes 112 of the upper case 111, the barrier parts 123 provided on both side portions of the mounting plate 122 so as to come into close contact with the inner surfaces of the upper case 111 and the lower case 115, thereby providing a waterproof function, and board insertion parts 124 provided at the lower end portion of the mounting plate 122 so that the PCB 130 is inserted and fixed to the board insertion parts 124.

First, the rubber keypad 120 may be made of a rubber or silicone material so as to be provided with elasticity and durability. Therefore, for example, when a part of the upper case 111 comes into contact with the rubber keypad 120, the effect of pressing the part of the upper case 111 can be generated by the elastic force of the rubber keypad 120, and thus generated effect allows the remote control 100 of this embodiment to have a waterproof function.

In addition, protrusion members 125 are arranged on the lower surface of the mounting plate 122 of the rubber keypad 120 so as to respectively correspond to the buttons 121 (see FIG. 4), so that when the buttons 121 are pressed, the pressing force may be transmitted to the PCB 130 by the protrusion members 125.

Referring to FIG. 3, the barrier parts 123 of the rubber keypad 120 of this embodiment come into close contact with the inner surface of the upper case 111 and the inner surface of the lower case 115, where the upper case 111 and the lower case 115 come into contact with each other, thereby blocking penetration of water or moisture between the upper case 111 and the lower case 115.

The barrier parts 123 may be symmetrically provided on both side portions of the mounting plate 122, as shown in FIG. 3. Therefore, when the upper case 111 and the lower case 115 are coupled to each other with the rubber keypad 120 interposed between them, the inner surfaces of the side portions of the upper case 111 and the inner surfaces of the side portions of the lower case 115 come into close contact with the outer surfaces of the barrier parts 123, thereby providing a waterproof function.

At this time, as described above, since the barrier parts 123 are made of a rubber or silicone material having elasticity, the inner surfaces of the case 110 and the inner surfaces of barrier parts 123 can be completely in close contact with each other through the coupling between the upper case 111 and the lower case 115.

In other words, since the barrier parts 123 have the structure of pressing the inner surfaces of the upper case 111 and lower case 115 by elastic force, the barrier parts 123 can be firmly adhered to and fixed to the inner surfaces of the upper case 111 and lower case 115. Therefore, penetration of water or moisture between the upper case 111 and the lower case 115 can be blocked by the barrier parts 123.

Referring to FIG. 3, the upper and lower cases 111, 115 and the rubber keypad 120 may be pre-manufactured such that contact portions thereof correspond to each other in shape. That is, the shape of the inner surfaces of the upper and lower cases 111, 115 may be formed according to the shape of the barrier parts 123 of the rubber keypad 120, and thus the case 110 and the barrier parts 123 can match each other.

Meanwhile, the rubber keypad 120 of this embodiment may include the board insertion parts 124 that surround and fix the PCB 130. The board insertion parts 124 protrude downward from both ends of the lower end portion of the mounting plate 122 so as to cover the side portions of the PCB 130, as shown in FIG. 3.

In other words, the width of the board insertion parts 124 corresponds to the width of the PCB 130, so that the PCB 130 can be inserted into and coupled to the board insertion parts 124 and then embedded in the case 110 in the inserted and coupled state.

In this way, since the board insertion parts 124 surround and protect the PCB 130, penetration of water or moisture into the case 110 can be prevented by the barrier parts 123 as described above and the PCB 130 can be protected by the board insertion parts 124. Therefore, waterproof function for the PCB 130 can be implemented more reliably.

Meanwhile, in the remote control 100 of this embodiment, a waterproof function may be provided between the buttons 121 and the button holes 112. Referring to FIG. 3, each of the plurality of button holes 112 of the upper case 111 includes a protruding rib 113 that protrudes inward from the upper case 111.

Therefore, when the rubber keypad 120 is coupled to the upper case 111, the lower end of the protruding rib 113 of the upper case 111 comes into close contact with the upper surface of the mounting plate 122 where the button 121 is provided, so that a waterproof function can be provided between the button 121 and the button hole 112.

As described above, since the mounting plate 122 is made of rubber or silicon, when the lower end of the protruding rib 113 is in close contact with the mounting plate 122, on the contrary, pressure is generated from the mounting plate 122 toward the protruding rib 113 by elastic force, so that water or moisture can be prevented from penetrating between the button 121 and the button hole 112.

Meanwhile, as shown in FIG. 4 to FIG. 6, the lower case 115 of this embodiment is provided with the battery groove 117, and the battery part 150 to which the battery 151 is mounted can be detachably coupled.

The battery part 150 of this embodiment may include, as shown in FIG. 5 and FIG. 6, a battery mounting frame 152 in which the battery 151 is mounted, a battery cover member 153 provided at an end portion of the battery mounting frame 152 so as to cover the battery groove 117, and a close contact member 154, which has an O-ring shape and is fitted into the battery mounting frame 152 so as to be disposed on an inner surface of the battery cover member 153.

First, the battery mounting frame 152 may be provided with a frame, on which two batteries 151 are mounted, and hook parts 152a at a front end facing the battery groove 117, wherein the hook parts 152a are held on or released from hooked parts provided on the battery groove 117.

The battery cover member 153 may be provided at an end portion of the battery mounting frame 152 so as to correspond to the open shape of the battery groove 117.

Therefore, the battery part 150 of this configuration can be coupled to or separated from the battery groove 117, wherein in order to prevent water or moisture from entering between the battery cover member 153 and the battery groove 117 and entering the inside of the battery groove 117, the close contact member 154 is fitted to the battery mounting frame 152 so as to be disposed on the inner surface of the battery cover member 153.

When the battery part 150 is coupled to the battery groove 117, as shown in FIG. 6, the close contact member 154 of this embodiment is placed so as to be in close contact with a side wall 117a that forms the battery groove 117 and the inner surface of the battery cover member 153, so that water or moisture can be prevented from entering the battery groove 117.

Meanwhile, in order to fix the battery cover member 153 with respect to the side wall 117a that forms the battery groove 117, the side wall of the battery groove 117 and the battery cover member 153 may be coupled by means of a screw 157 in a region outside the close contact member 154, as shown in FIG. 6.

In this way, according to the one embodiment of the present invention, by providing a waterproof structure in all gaps in the case 110, it is possible to prevent water or moisture from penetrating into the case 110, thereby enhancing durability.

In other words, by providing the waterproof function between the upper case 111 and the lower case 115, between the buttons 121 and the button holes 112, between the rubber keypad 120 and the PCB 130, and between the battery part 150 and the battery groove 117, it is possible to prevent failure due to penetration of water or moisture, etc.

Although the specific embodiment according to the present invention have been described so far, various modifications can be made thereto without departing from the scope of the present invention. Therefore, the scope of the present invention should not be limited to the described embodiment and should not be defined, but should be defined by not only the scope of the claims to be described later but also those equivalents to the scope of these claims.

As described above, the present invention has been described by the limited embodiment and drawings, but the present invention is not limited to the above embodiment, and those skilled in the art in the field to which the present invention belongs can make various modifications and changes. Therefore, the spirit of the present invention should be grasped only by the claims described below, and all equivalent or equivalent modifications thereof will be said to belong to the scope of the spirit of the present invention.

### EXPLANATION OF REFERENCE NUMERALS

100: Remote control with a waterproof function
110: Case
111: Upper case
112: Button hole
112a: Microphone hole
113: Protruding rib
115: Lower case
117: Battery groove
120: Rubber keypad
121: Button
122: Mounting plate
123: Barrier part
124: Board insertion part
125: Protrusion member
130: PCB
150: Battery part
151: Battery
152: battery mounting frame
153: battery cover member
154: Close contact member
157: Screw (for battery part)
160: Screw (for case)

What is claimed is:

1. A remote control with a waterproof function, comprising:
a case including an upper case having a plurality of button holes and a lower case assembled to the upper case at a lower portion of the upper case;
a printed circuit board PCB embedded between the upper case and the lower case; and
a rubber keypad, which is embedded between the upper case and the lower case so as to be mounted to surround the side portions of the PCB and has a plurality of buttons that pass through the plurality of button holes and barrier parts that come into close contact with the inner surface of the upper case and the inner surface of the lower case, where the upper case and the lower case come into contact with each other.

2. The remote control with a waterproof function according to claim 1, wherein the barrier parts are provided on both sides of a mounting plate of the rubber keypad on which the plurality of button holes are provided, and when the upper case and the lower case are coupled to each other with the rubber keypad interposed between the upper case and the lower case, the inner surfaces of the side portions of the upper case and the inner surfaces of the side portions of the lower case come into close contact with the outer surfaces of the barrier parts so as to provide a waterproof function.

3. The remote control with a waterproof function according to claim 2, wherein the rubber keypad provided with the barrier parts is made of a rubber or silicone material so that when the rubber keypad is coupled to the upper case and the lower case with the barrier parts interposed between the upper case and the lower case, the outer surfaces of the barrier parts press the upper case and the lower case owing to the elastic force provided in the barrier parts so that the barrier parts come into close contact with the upper case and the lower case.

4. The remote control with a waterproof function according to claim 2, wherein the rubber keypad is provided with board insertion parts which protrude downward from both ends of the lower end portion of the mounting plate so as to surround the side portions of the PCB, and the width of the board insertion parts and the width of the PCB correspond to each other so that the PCB is embedded in the case while being inserted into the board insertion parts.

5. The remote control with a waterproof function according to claim 2, wherein protruding parts are provided on any one of the side portions of the upper case or the side portions of the lower case, and recessed parts corresponding in shape to the protruding parts are provided on the other one of the side portions of the upper case or the side portions of the lower case so as to come into surface contact with the protruding parts.

6. The remote control with a waterproof function according to claim 2, wherein each of the plurality of button holes of the upper case includes a protruding rib that protrudes inward from the upper case, and when the rubber keypad is coupled to the upper case, the lower end of the protruding rib comes into close contact with the upper surface of the mounting plate of the rubber keypad, which is provided with the buttons.

7. The remote control with a waterproof function according to claim 1, further comprising a battery part in which a battery is detachably coupled to a battery groove provided in the lower case.

8. The remote control with a waterproof function according to claim 7, wherein
the battery part includes:
a battery mounting frame in which the battery is mounted;
a battery cover member provided at an end portion of the battery mounting frame so as to cover the battery groove; and
a close contact member, which has an O-ring shape and is fitted into the battery mounting frame so as to be disposed on an inner surface of the battery cover member,
wherein when the battery part is coupled to the battery groove, the close contact member comes into close contact with sidewalls, which form the battery groove, and the battery cover member.

9. The remote control with a waterproof function according to claim 8, wherein the sidewalls that form the battery groove and the battery cover member are coupled by means of a screw in order to fix the battery cover member to the sidewalls that form the battery groove, and the screw is coupled in a region outside the contact member.
